(19) United States
(12) Patent Application Publication
(10) Pub. No.: US 2001/0042903 A1
(43) Pub. Date: Nov. 22, 2001

(54) INTER-METAL DIELECTRIC LAYER STRUCTURE AND ITS FORMING METHOD

(76) Inventors: CHI-FA LIN, HSINCHU (TW); WEI-TSU TSENG, HSINCHU (TW); MIN-SHINN FENG, HSINCHU (TW)

Correspondence Address: LAFF WHITESEL CONTE & SARET LLP, 401 NORTH MICHIGAN AVENUE, CHICAGO, IL, 606114212

(21) Appl. No.: 09/304,386

(22) Filed: May 4, 1999

(30) Foreign Application Priority Data
Nov. 19, 1998 (TW) 87119209

(51) Int. Cl. H01L 21/469; H01L 21/31; H01L 23/58

(52) U.S. Cl. 257/635

(57) ABSTRACT

An inter-metal dielectric (IMD) layer structure and its forming method are disclosed. The IMD layer structure is formed between a first conducting layer and a second conducting layer and includes a first dielectric layer overlying the first conducting layer, a glass layer overlying the first dielectric layer, an etching stop layer overlying the glass layer, and a second dielectric layer overlying the etching stop layer under the second conducting layer. The etching rate of the etching stop layer is relatively low so that it can prevent the glass layer etched out. Therefore, a long-time etching can be used to obtain a better through hole profile.

### FIELD OF THE INVENTION

The present invention relates to an inter-metal dielectric (IMD) layer structure and its forming method, and especially to an IMD layer structure and its forming method to be applied in an integrated circuit having multilevel metal layer structures.

### BACKGROUND OF THE INVENTION

At the present time, there is a tendency to increase the denseness and complexity of the semiconductor device and thus a single metal layer for connecting transistor, resistor, capacitor, etc. can not satisfy the current requirement. It is necessary to utilize the multilevel metal layer to achieve the connection of entire integrated circuit. During the multilevel metallization process, an inter-metal dielectric (IMD) layer is formed between two metal layers (a sandwich type) to isolate these two metal layers and attain the purpose of local planarization simultaneously for etching the formation of upper metal layer. In addition, the pattern of the conducting line can be precisely transferred by photolithography and etching technique.

As shown in FIG. 1, a first oxide layer 12 is formed on the first conducting layer 11 by plasma enhanced chemical vapor deposition (PECVD) method at first. Then, a spin on glass (SOG) layer 13 is formed on the first oxide layer 12 and a second oxide layer 14 is formed on the SOG layer by PECVD. Besides, the local planarization of the SOG layer, as people known, usually is made by non-etching back (NEB) method or partially etching back (PEB) method and there is no need to describe these methods here.

The two metal layers 11, 15, however, are not completely isolated. An Al plug is usually formed inside the through hole 21 by the sputtering or deposition method for connecting the first and second metal layers 11, 15, as shown in FIG. 2. The through hole 21 is formed by dry etching or wet etching process and includes two regions, i.e. the vertical region 212 and inclined region 211. Because the step coverage of the Al plug formed by the sputtering or deposition method is so not good enough, the inclined region 211 formed by wet etching process can ensure that the Al atoms can be deposited inside the through hole and the reliability of the connection of the metal layers can be increased.

In the wet etching process of forming the inclined region 211, the etching thickness typically are controlled by changing the etching time. Although a good inclined profile is formed by a long-time etching, the oxide layers and the SOG layer are not suitable to be etched. The structure of the oxide layers usually contains a lot of pin holes and the SOG layer is a loose and water-contained polymer layer. The ratio of the etching rate of the oxide layers to that of the SOG layer is about 1 to 10. Therefore, the second oxide layer 14 will be etched and the SOG layer 13 will be also etched through along the pin holes during the wet etching process so that the SOG layer 13 will be etched out to split the second oxide layer 14.

Moreover, as shown in FIG. 3, before the first metal layer 33 is formed on the chip 30, a field oxide layer 31 having a thickness of 4000 Å and an inter-layer dielectric layer 32 having a thickness of 6000 Å have been formed. Consequently, a large thickness difference is already existed at the edge of the first metal layer 33. While the IMD layer 35˜37 is formed on the first metal layer 33, the step coverage ratio (the thickness at a to that at b) usually is less than 60%. The metal pattern edge stress concentration effect will further increase the etching rate at the edge of the first metal layer 33. If the temperature is changed, some cracks will be formed on the second oxide layer 37 at edge of the channel region 34 and the first metal layer 33. These cracks will increase the etching rate of the second oxide layer 37.

To avoid this problem, the etching time shall be decreased to let the second oxide layer have a thickness of at least 3000 Å. This thickness is called the safety margin 22 as shown in FIG. 2. However, there still are some problems in the formation of the second oxide layer having the safety margin 22. If the etching time is short, the inclined profile will not be very good. If the etching time is long, the total thickness difference of the second oxide layer will be increased.

It is therefore attempted by the applicant to deal with the above situation encountered with the prior art.

### SUMMARY OF THE INVENTION

An object of the present invention is to provide an inter-metal dielectric (IMD) layer structure formed between a first conducting layer and a second conducting layer.

The IMD layer includes a first dielectric layer, a glass layer, an etching stop layer, and a second dielectric layer. The first dielectric layer is formed overlying the first conducting layer structure. Thereafter, the glass layer is formed overlying the first dielectric layer. Thereafter, the etching stop layer is formed overlying the glass layer. Finally, the second dielectric layer is formed overlying the etching stop layer. Because the etching stop layer has a very low etching rate, it can protect the glass layer from being etched out. Therefore, a long-time etching can be used to obtain a better through hole profile.

Because the etching stop layer has a lower etching rate than that of the glass layer and the oxide layer, a better through-hole profile can be obtained.

According to the present invention, the first and second dielectric layers are oxide layers, preferably silicon oxide layers. The first conducting layer and the second conducting layer are metal layers, preferably Al layers. The glass layer is a spin on glass (SOG) layer. In addition, the dielectric layers and the etching stop layer are formed by plasma enhanced chemical vapor deposition (PECVD). The etching stop layer having a low etching rate can be a boron nitride layer, a silicon nitride layer, a silicon oxide layer, or an amorphous silicon layer. The thickness of the etching stop layer generally is ranged from 200 Å to 1000 Å.

A further object of the present invention is to provide a method for forming an inter-metal dielectric layer structure between a first conducting layer and a second conducting layer. At first, a first dielectric layer is formed over the first conducting layer and a glass layer is formed over the first dielectric layer. Then, an etching stop layer having a low etching rate is formed over the glass layer. Finally, a second dielectric layer is formed overlying the etching stop layer. The etching stop layer can protect the second dielectric layer from being etched through because it has a very low etching rate. Therefore, a longtime etching can be used to obtain a better through-hole profile.

The present invention may best be understood through the following description with reference to the accompanying drawings, in which:

### BRIEF DESCRIPTION OF THE DRAWINGS

FIG. 1 is a diagram schematically showing a conventional IMD layer structure;

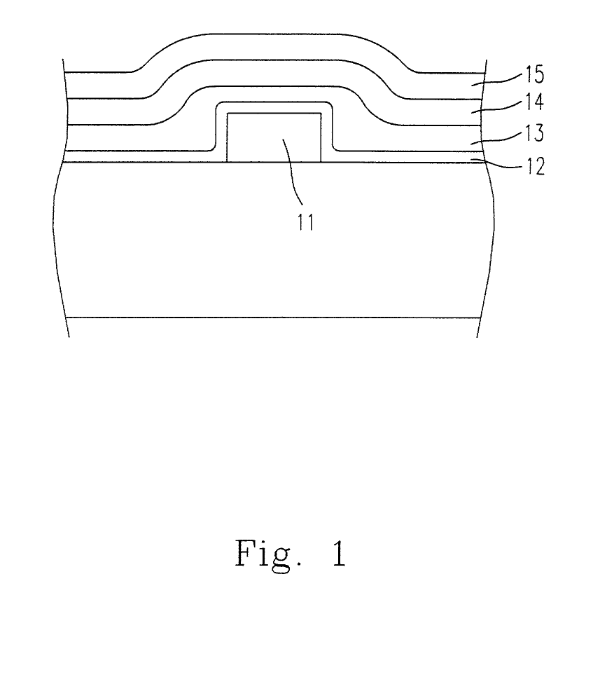

FIG. 2 is a diagram schematically showing the through hole of the conventional IMD layer structure;

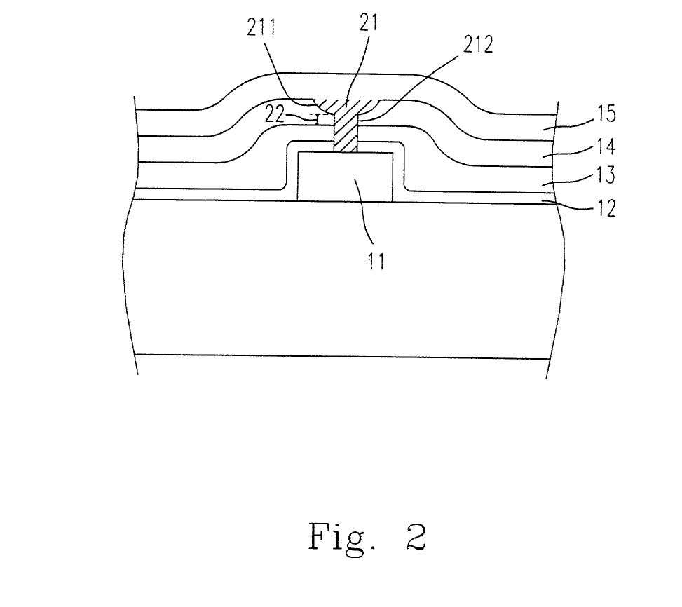

FIG. 3 is a diagram schematically showing the area between the channel region and the first metal layer of the conventional IMD layer structure;

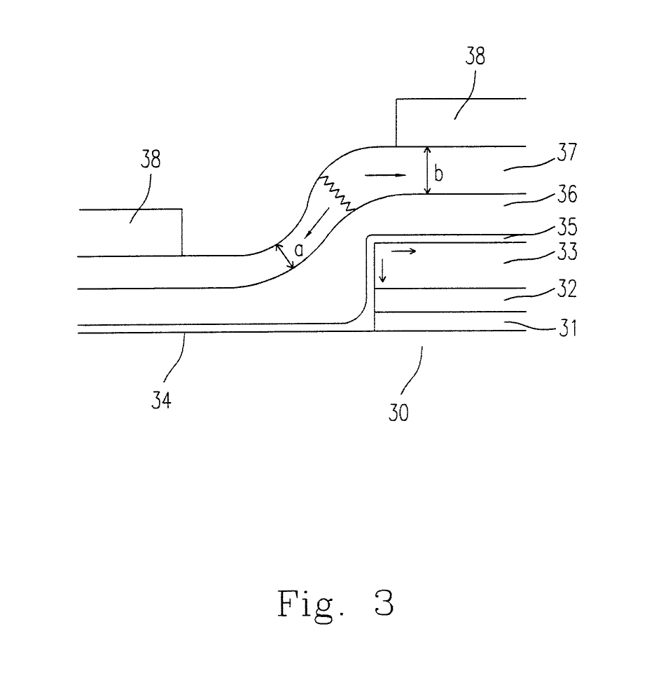

FIG. 4 is a diagram schematically showing an IMD layer structure of the present invention;

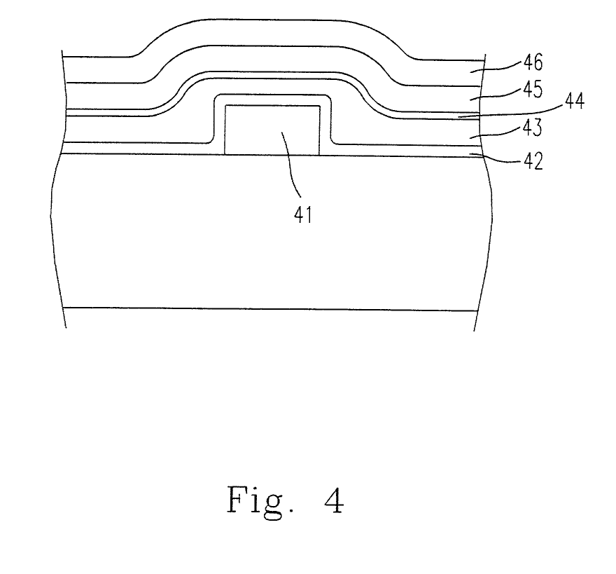

FIG. 5 is a diagram schematically showing the through hole of the IMD layer structure according to the present invention; and

FIG. 6 is a diagram schematically showing the area between the channel region and the first metal layer of the IMD layer structure according to the present invention.

### DETAILED DESCRIPTION OF THE PREFERRED EMBODIMENTS

Please refer to 4 showing the IMD layer structure of the present invention. The inter-metal dielectric layer structure is formed between a first conducting layer 41 and a second conducting layer 46. The first and second conducting layers 41, 46, preferably metal layers, such as alumina layers.

The IMD layer of the present invention includes a first dielectric layer 42 overlying the first metal layer 41, a glass layer 43 overlying the first dielectric layer 42, an etching stop layer 44 overlying the glass layer 43, and a second dielectric layer 45 overlying the etching stop layer 44 under the second conducting layer 46. The first dielectric layer 42 and the second dielectric layer 45 preferably are oxide layers, especially silicon oxide layers. The glass layer 43 is a spin on glass (SOG) layer.

The main feature of the IMD layer of the present invention is that it includes the etching stop layer 44 for preventing the SOG layer 43 from being etched through the pin holes after the second dielectric layer 45 is etched. The thickness of the etching stop layer generally is ranged from 200 Å to 1000 Å. Consequently, a long-time etching can be used to obtain a better through hole profile without the problems encountered with the prior art. The etching stop layer can be a boron nitride layer, a silicon nitride layer, a silicon oxide layer, or an amorphous silicon layer. The etching stop layer 44 is made of a material having a very low etching rate. When the through hole is formed, the etching stop layer 44 can prevent the second oxide layer 45 from being etched through along the pin holes to the SOG layer 43.

The dielectric layers and the etching stop layer preferably are formed by PECVD. Further, the etching stop layer and the second dielectric layer preferably are formed in the same PECVD chamber under a temperature lower than 500° C. to simplify the processes.

For example, if a etching stop layer made of silicon nitride and having a thickness of 200 Å to 1000 Å is formed by PECVD and is etched by the wet etching agent is buffer oxide etcher (BOE), the ratio of the etching rate of the etching stop layer, the silicon oxide layer, and the SOG layer are about 1:10:100. Therefore, the etching stop layer can successfully prevent the SOG layer 43 from being etched out and make the second oxide layer 45 split.

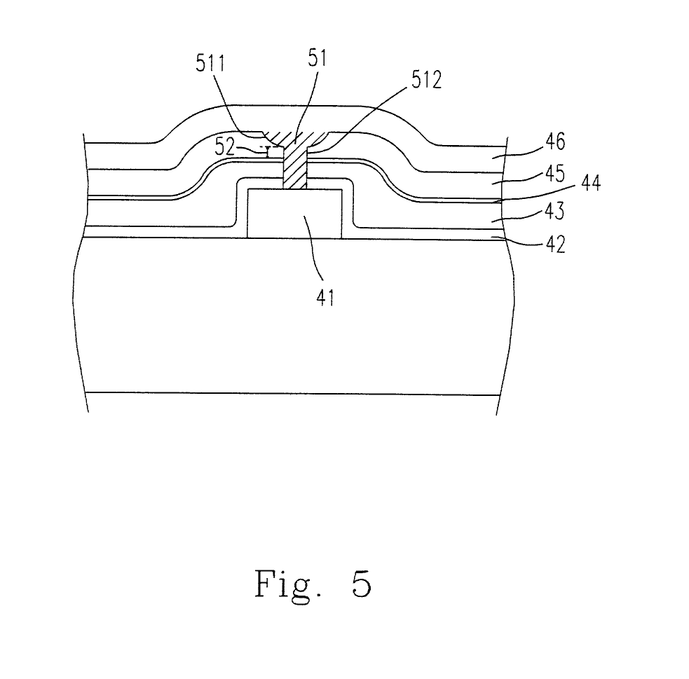

FIG. 5 shows the through hole of the IMD layer structure according to the present invention. A metal plug is formed inside the through hole 51 and the through hole structure includes an inclined region 511 and a vertical region 512. Because the etching stop layer 44 can prevent the SOG layer 43 from being etched through the pin holes after the second dielectric layer 45 is etched out, a long-time etching and a thin safety margin 52 can be used to obtain a better through-hole profile.

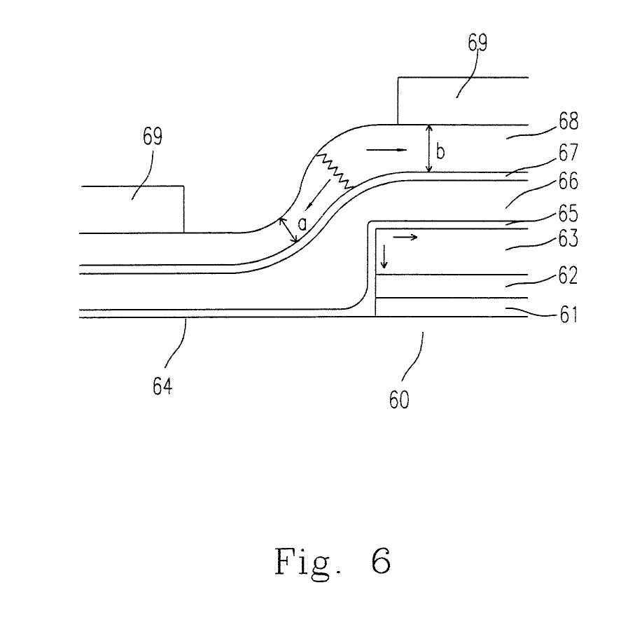

Besides, as shown in FIG. 6 the problem raised from the large thickness difference between the field oxide layer 61 and the inter-layer dielectric layer 62 can also be solved. Although the structure of the IMD layer is very weak at the edge of the first conducting layer 63, the etching stop layer still can prevent the SOG layer 66 from being etched by wet etching. Therefore, the IMD layer structure of the present invention is very useful and effective. Not only can all problems of the conventional IMD layer be solved, but a long-time etching and a better through-hole profile are obtained.

While the invention has been described in terms of what are presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An inter-metal dielectric layer structure formed between a first conducting layer and a second conducting layer, comprising:
a first dielectric layer overlying said first conducting layer;
a glass layer overlying said first dielectric layer;
an etching stop layer overlying said glass layer; and
a second dielectric layer overlying said etching stop layer under said second conducting layer.

2. The inter-metal dielectric layer structure according to claim 1, wherein said first dielectric layer and said second dielectric layer are oxide layers.

3. The inter-metal dielectric layer structure according to claim 2, wherein said oxide layers are silicon oxide layers.

4. The inter-metal dielectric layer structure according to claim 1, wherein said first conducting layer and said second conducting layer are metal layers.

5. The inter-metal dielectric layer structure according to claim 1, wherein said etching stop layer is selected from the group consisting of a boron nitride layer, a silicon nitride layer, a silicon oxide layer, and an amorphous silicon layer.

6. The inter-metal dielectric layer structure according to claim 1, wherein said etching stop layer has a lower etching rate than that of said glass layer.

7. The inter-metal dielectric layer structure according to claim 1, wherein said first dielectric layer is formed by plasma enhanced chemical vapor deposition (PECVD).

8. The inter-metal dielectric layer structure according to claim 7, wherein said etching stop layer is formed by PECVD.

9. The inter-metal dielectric layer structure according to claim 8, wherein said second dielectric layer is formed by PECVD

10. The inter-metal dielectric layer structure according to claim 9, wherein said etching stop layer and said second dielectric layer are formed in the same PECVD chamber.

11. The inter-metal dielectric layer structure according to claim 1, wherein said etching stop layer has a thickness ranged from 200 Å to 1000 Å.

12. The inter-metal dielectric layer structure according to claim 1, wherein said glass layer is a spin on glass (SOG) layer.

13. A method for forming an inter-metal dielectric layer structure between a first conducting layer and a second conducting, comprising:
forming a first dielectric layer overlying said first conducting layer;
forming a glass layer overlying said first dielectric layer;
forming an etching stop layer overlying said glass layer; and
forming a second dielectric layer overlying said etching stop layer.

14. The method according to claim 13, wherein said first dielectric layer and said second dielectric layer are oxide layers

15. The method according to claim 14, wherein said oxide layers are silicon oxide layers.

16. The method according to claim 13, wherein said etching stop layer is selected from the group consisting of a boron nitride layer, a silicon nitride layer, a silicon oxide layer, and an amorphous silicon layer.

17. The method according to claim 13, wherein said etching stop layer has a lower etching rate than that of said glass layer.

18. The method according to claim 13, wherein said first dielectric layer is formed by plasma enhanced chemical vapor deposition (PECVD).

19. The method according to claim 18, wherein said etching stop layer is formed by PECVD.

20. The method according to claim 19, wherein said second dielectric layer is formed by PECVD.

21. The method according to claim 20, wherein said etching stop layer and said second dielectric layer are formed in the same PECVD chamber.

22. The method according to claim 13, wherein said etching stop layer has a thickness ranged from 200 Å to 1000 Å.

23. The method according to claim 13, wherein said glass layer is a SOG layer.
